(19) United States
(12) Patent Application Publication
(10) Pub. No.: US 2026/0313946 A1
(43) Pub. Date: Oct. 8, 2026

(54) FINFET DEVICE STRUCTURE WITH EXTRA FIN

(71) Applicant: TAIWAN SEMICONDUCTOR MANUFACTURING COMPANY, LTD., Hsinchu (TW)

(72) Inventors: Yi Hong WANG, Taichung (TW); Hui-Hsuan KUNG, Taichung (TW); Yi-Lii HUANG, Hsinchu (TW); Chih-Hsiao CHEN, Taichung (TW)

(21) Appl. No.: 19/713,812

(22) Filed: Jun. 19, 2026

Related U.S. Application Data
(63) Continuation of application No. 18/237,811, filed on Aug. 24, 2023, now Pat. No. 12,707,669.

(51) Int. Cl. H10D 30/62; H10D 30/01; H10D 84/01; H10D 84/85

(52) U.S. Cl. CPC H10D 30/6211; H10D 30/024; H10D 84/0193; H10D 84/853

(57) ABSTRACT

Embodiments of the present disclosure provide a FinFET semiconductor including a first set of fin structures that are active, a source/drain (S/D) region in contact with the first set of fin structures, a second set of fin structures separated, via a shallow trench isolation (STI) feature, from the first set of fin structures, a contact etch stop layer (CESL) over the S/D region and over the second set of fin structures, and a gate over the first set of fin structures and over the second set of fin structures, the gate including a gate dielectric and a gate electrode over the gate dielectric. The second set of fin structures includes one or more non-active fin structures that are in contact with the CESL without being in contact with the S/D region.

### CROSS-REFERENCE TO RELATED APPLICATIONS

This application is a continuation application of U.S. patent application Serial No. 18/237,811 filed Aug. 24, 2023, which is incorporated by reference in their entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down presents new challenges.

In pursuit of higher device density, higher performance, and lower costs, challenges from both fabrication and design issues have resulted in the development of three-dimensional designs, such as a multi-gate field effect transistor (FET), including a FinFET. In a FinFET, the channel region includes a non-planar fin shape that is surrounded on three sides by the gate electrode, which allows for fuller depletion in the channel and results in less short-channel effects and better gate control. As transistor dimensions are continually scaled down, further improvements of the FinFET are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic top view of an example semiconductor device, according to embodiments of the present disclosure.

FIG. 2 is a schematic cross-sectional view, of an example FinFET device of FIG. 1, taken along section line A-A’, according to embodiments of the present disclosure.

FIG. 3 is a schematic cross-sectional view, of another example FinFET device of FIG. 1, taken along section line B-B’, according to embodiments of the present disclosure.

FIG. 4 is a schematic cross-sectional view, of an example FinFET device of FIG. 1, taken along section line C-C’, according to embodiments of the present disclosure.

FIG. 5 is a schematic cross-sectional view, of another example FinFET device of FIG. 1, taken along section line D-D’, according to embodiments of the present disclosure.

FIG. 6 is a schematic top view of an example semiconductor device illustrating control of spacing of extra fin structures, according to embodiments of the present disclosure.

FIG. 7 is a schematic cross-sectional view, of an example FinFET device of FIG. 6, according to embodiments of the present disclosure.

FIG. 8 is a schematic cross-sectional view, of another example FinFET device of FIG. 6, according to embodiments of the present disclosure.

FIGS. 9-12 are schematic cross-sectional views of example FinFET devices of FIG. 1 or 6, according to embodiments of the present disclosure.

FIGS. 13-15 are schematic cross-sectional views, taken outside the gate region, of example FinFET devices of FIG. 1 or 6, according to embodiments of the present disclosure.

FIGS. 16A-16C schematically illustrate various stages of forming the epitaxial features of FIG. 14, according to embodiments of the present disclosure.

FIGS. 17A-17C schematically illustrate various stages of forming the epitaxial features of FIG. 15, according to embodiments of the present disclosure.

FIG. 18 illustrates schematic top views of example semiconductor devices that incorporate one or more aspects described herein, according to embodiments of the present disclosure.

FIG. 19 is a flow chart of a method of forming a FinFET of a semiconductor device, according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and also may include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to FinFETs, implementations of some aspects of the present disclosure may be used in other processes and/or in other devices, such as planar FETs, nanosheet channel FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The foregoing broadly outlines some aspects of embodiments described in this disclosure. A person having ordinary skill in the art will readily understand other modifications that may be made are contemplated within the scope of this disclosure. In addition, although method embodiments may be described in a particular order, various other method embodiments may be performed in any logical order and may include fewer or more steps than what is described herein. In the present disclosure, a source/drain region(s) may refer to a source or a drain, individually or collectively dependent upon the context.

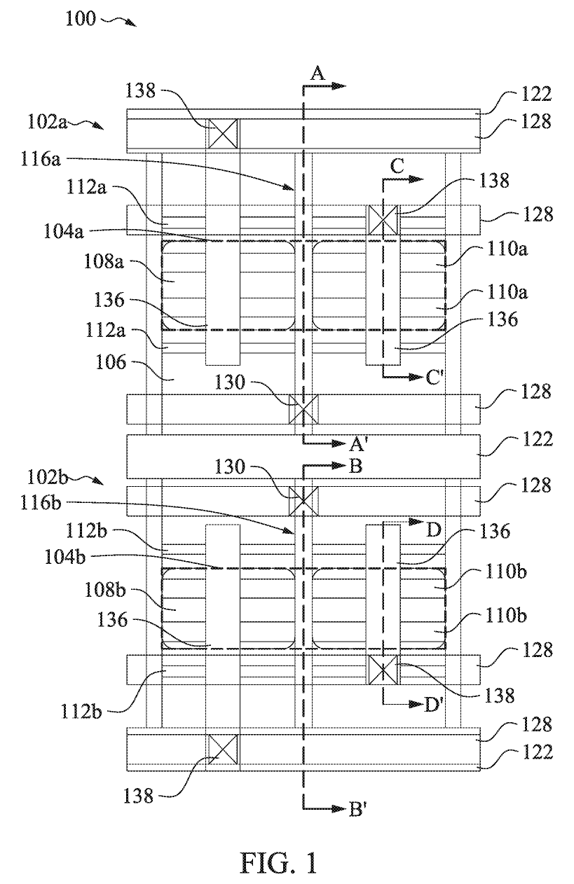

FIG. 1 is a schematic top view of an example semiconductor device 100, according to embodiments of the present disclosure. As shown in FIG. 1, the semiconductor device 100 may include a first FinFET device 102a and a second FinFET device 102b. The first FinFET device 102a may include a first active region 104a that includes, for example, a first source/drain (S/D) region 108a. The second FinFET device 102b may include a second active region 104b that includes, for example, a second S/D region 108b. As used herein, the term “active region” refers to a region of the device (e.g., the area inside the dashed lines shown in FIG. 1) that is associated with (e.g., in contact with) one or more n-type or p-type doped S/D features. The first active region 104a and the second active region 104b may be materially and/or functionally different from each other (e.g., based on material and/or functional differences between the first S/D region 108a and the second S/D region 108b, as described in more detail below).

The semiconductor device 100 may include a substrate 106. The first FinFET device 102a and the second FinFET device 102b may be fabricated on the substrate 106. The substrate 106 may be a semiconductor substrate. The substrate 106 may include a single crystalline semiconductor material such as, but not limited to, silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb), indium phosphide (InP), and/or combinations thereof. In some embodiments, the substrate 106 may be made of silicon. In some embodiments, the substrate 106 may be a silicon-on-insulator (SOI) substrate having an insulating layer (not shown) disposed between two silicon layers. For example, the insulating layer may be an oxygen-containing layer.

The substrate 106 may include various regions that have been doped with impurities (e.g., dopants having p-type or n-type conductivity). Depending on circuit design, the dopants may be, for example, boron for p-type field effect transistors (p-type FETs) and phosphorus for n-type field effect transistors (n-type FETs). For example, the substrate 106 may include one or more of a p-type well (“p-well”) and an n-type well (“n-well”).

The semiconductor device 100 may include a plurality of fin structures that are defined on (e.g., formed from) the substrate 106. In some embodiments, the fin structures may be made of Si, Ge, GaAs, SiC, GaN, C, In, other suitable materials, and/or combinations thereof. A mask structure may be formed over the substrate 106 prior to forming the fin structures. The mask structure may include a pad layer and a hard mask. The pad layer may be an oxygen-containing layer, such as a SiO₂ layer, or a nitrogen-containing layer, such as Si₃N₄. The mask structure may be formed by any suitable deposition process, such as chemical vapor deposition (CVD) process.

The fin structures may be fabricated using suitable processes including photolithography and etch processes. For example, the photolithography process may include forming a photoresist layer over the mask structure, exposing the resist to a pattern, performing post-exposure bake processes, and developing the resist to form a patterned resist. The patterned resist may then be used to protect regions of the substrate 106, and layers formed thereon, while an etch process forms trenches in unprotected regions through the mask structure and into the substrate 106, thereby leaving the extending fin structures. The trenches may be etched using a dry etch (e.g., RIE), a wet etch, and/or combinations thereof.

The first FinFET device 102a may include a first set of fin structures 110a and a second set of fin structures 112a. As used herein, the term “set” may include one or more of the respective features (e.g., one or more fin structures). The fin structures 110a, of the first set, are active (e.g., defined in the first active region 104a, or in connection with the first source/drain region 108a). For example, at least portions of the fin structures 110a (e.g., longitudinal end portions) may be recessed to allow respective S/D features of the first S/D region 108a to be epitaxially grown from the fin structures 110a.

The second set of fin structures 112a may be referred to as “extra fin structures” or “auxiliary fin structures.” The extra fin structures may be active or non-active based on the structure of the FinFET device. In FIGS. 1-5, the fin structures 112a, of the second set, are non-active (e.g., being defined outside the first active region 104a, or not in connection with the first source/drain region 108a). For example, the fin structures 112a may be separated from the first S/D region 108a by one or more dielectric materials (e.g., contact etch stop layer (CESL) 140), as described in more detail below.

The second FinFET device 102b may include a third set of fin structures 110b and a fourth set of fin structures 112b. The fin structures 110b, of the third set, are active (e.g., defined in the second active region 104b, or in connection with the second source/drain region 108b). For example, at least portions of the fin structures 110b (e.g., longitudinal end portions) may be recessed to allow respective S/D features of the second S/D region 108b to be epitaxially grown from the fin structures 110b. The fourth set of fin structures 112b, like the second set, may be referred to as “extra fin structures” or “auxiliary fin structures.” The extra fin structures may be active or non-active based on the structure of the FinFET device. In FIGS. 1-5, the fin structures 112b, of the fourth set, are non-active (e.g., being defined outside the second active region 104b, or not in connection with the second source/drain region 108b). For example, the fin structures 112b may be separated from the second S/D region 108b by one or more dielectric materials (e.g., CESL 140), as described in more detail below.

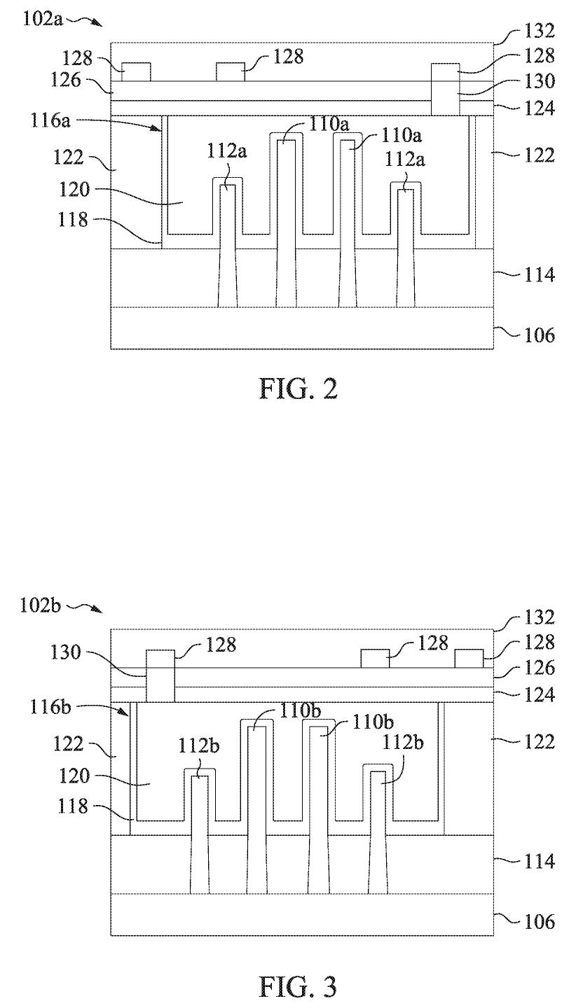

FIG. 2 is a schematic cross-sectional view, of an example FinFET device of FIG. 1, taken along section line A-A’, according to embodiments of the present disclosure. FIG. 3 is a schematic cross-sectional view, of another example FinFET device of FIG. 1, taken along section line B-B’, according to embodiments of the present disclosure.

As shown in FIGS. 2-3, the semiconductor device 100 may include a shallow trench isolation (STI) feature (e.g., insulating material 114) around a lower portion of the fin structures 110a, 112a, 110b, 112b. For example, the insulating material 114 may be formed in the trenches between the fin structures 110a, 112a, 110b, 112b. In some embodiments, the fin structures 110a, 110b are partially embedded in the insulating material 114. In some embodiments, the fin structures 112a, 112b may be partially or fully embedded in the insulating material 114 depending on the function of the fin structures 112a, 112b. In some embodiments, a planarization operation, such as a chemical mechanical polishing (CMP) method, and/or an etch-back method, may be performed to remove a portion of the insulating material 114 and/or to expose the fin structures (e.g., top surfaces of the fin structures). The insulating material 114 may be made of silicon oxide, silicon nitride, silicon oxynitride (SiON), SiOCN, SiCN, fluorine-doped silicate glass (FSG), a low-k dielectric material, or any suitable dielectric material. The insulating material 114 may be formed by any suitable method, such as low-pressure chemical vapor deposition (LPCVD), plasma enhanced CVD (PECVD), or flowable CVD (FCVD).

The first FinFET device 102a may include a first gate 116a. The first gate 116a crosses over the first set of fin structures 110a and the second set of fin structures 112a. The second FinFET device 102b may include a second gate 116b. The second gate 116b crosses over the third set of fin structures 110b and the fourth set of fin structures 112b. Portions of the fin structures that are located between two source/drain regions 108a, 108b or in a gate region (e.g., being overlapped by the first gate 116a or the second gate 116b) may be defined as “channels.” In some embodiments, the first gate 116a and the second gate 116b may be combined together as a single, integral gate structure. The gate 116 (e.g., first gate 116a and second gate 116b) may include a gate dielectric 118 and a gate electrode 120. The gate dielectric 118 may be located between (e.g., at an interface between) the fin structures (e.g., top and side surfaces of the fin structures) and the gate electrode 120. In some embodiments, the gate dielectric 118 may be made of Si, O, Hf, La, Zr, Zn, N, other suitable materials, and/or combinations thereof. In some embodiments, the gate dielectric 118 may include an interfacial layer and a high-k dielectric layer. For example, the interfacial layer may include a dielectric material, such as silicon oxide, hafnium silicate, or silicon oxynitride. High-k gate dielectrics, as used and described herein, include dielectric materials having a high dielectric constant, for example, greater than that of thermal silicon oxide, which is about 3.9. For example, the high-k dielectric layer may include hafnium oxide, titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al2O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), other suitable materials, and/or combinations thereof.

In some embodiments, the gate electrode 120 may include a single layer, or multi-layer, structure that includes a metal layer with a selected work function to enhance the device performance (work function metal layer), a liner layer, a wetting layer, an adhesion layer, a metal alloy, a metal silicide, and/or combinations thereof. For example, the gate electrode 120 may include Ag, Au, Rh, Mo, Zn, Nb, Ta, Zr, aluminum (Al), tungsten (W), nickel (Ni), titanium (Ti), ruthenium (Ru), cobalt (Co), platinum (Pt), copper (Cu), metal alloys such as titanium nitride (TiN), brass, phosphor bronze, cast steel, titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), tantalum carbide (TaC), or tantalum silicon nitride (TaSiN), other refractory metals, other suitable metal materials, and/or combinations thereof.

In practice, certain aspects of the material of the gate electrode 120 (which also may be referred to herein as a “work function metal” or “WFM”) are associated with device performance. For example, the material composition and/or thickness of the WFM may be used to tune (e.g., optimize) or otherwise adjust device performance. However, device scaling (to smaller dimensions) may result in gate volumes being limited, the WFM being harder to fill, and tuning of device threshold voltage (Vₜ) being more difficult to perform, with a resultant limitation on device types. Embodiments of the present disclosure address one or more of these issues, for example, through control of one or more extra fin structures, as described in more detail below.

Referring, collectively, to FIGS. 1-3, the gate 116 may extend lengthwise in a direction that is perpendicular to the fin structures. The gate 116 may terminate at one or more gate end dielectric features 122 (e.g., dielectric fin structures). For example, the one or more gate end dielectric features 122 may be located at first and second opposite longitudinal ends of the gate 116. In some implementations, the one or more gate end dielectric features 122 may be formed of silicon oxide, silicon nitride, silicon carbide, silicon oxynitride, silicon carbonitride, silicon oxycarbide, silicon oxycarbonitride, porous oxide, and/or combinations thereof.

In some embodiments, an optional etch stop dielectric layer 124 may be formed over the gate 116. For example, the etch stop dielectric layer 124 may be a blanket layer that is formed over a top surface of the gate 116 and over the one or more gate end dielectric features 122. In some embodiments, the etch stop dielectric layer 124 may be formed of low-k dielectric materials, such as tetraethylorthosilicate (TEOS) oxide, un-doped silicate glass, or doped silicon oxide, such as borophosphosilicate glass (BPSG), fused silica glass (FSG), phosphosilicate glass (PSG), boron doped silicon glass (BSG), and/or combinations thereof.

In some embodiments, an interlayer dielectric (ILD) layer 126 may be formed over the etch stop dielectric layer 124. In some embodiments, the ILD layer 126 may be formed of the same, or similar, material compositions as the etch stop dielectric layer 124.

In some embodiments, one or more metal lines 128, of a conductive layer, may be formed over the ILD layer 126. For example, the one or more metal lines 128 may extend lengthwise in a direction that is perpendicular to the gate 116 and/or parallel to the fin structures. In some embodiments, a gate contact via 130 may extend from a metal line 128, of the conductive layer, to the gate 116. For example, the gate contact via 130 may extend vertically in a direction that is perpendicular to the gate 116 and the fin structures. In some embodiments, the one or more metal lines 128 and the gate contact via 130 may be formed of titanium (Ti), titanium nitride (TiN), tantalum nitride (TaN), platinum (Pt), copper (Cu), aluminum (Al), ruthenium (Ru), tungsten (W), nickel (Ni), cobalt (Co), and/or combinations thereof.

In some embodiments, an inter metal dielectric (IMD) layer 132 may be formed over the conductive layer (e.g., surrounding the one or more metal lines 128). In some embodiments, the IMD layer 132 may be formed of the same, or similar, material compositions as the etch stop dielectric layer 124 and/or the ILD layer 126.

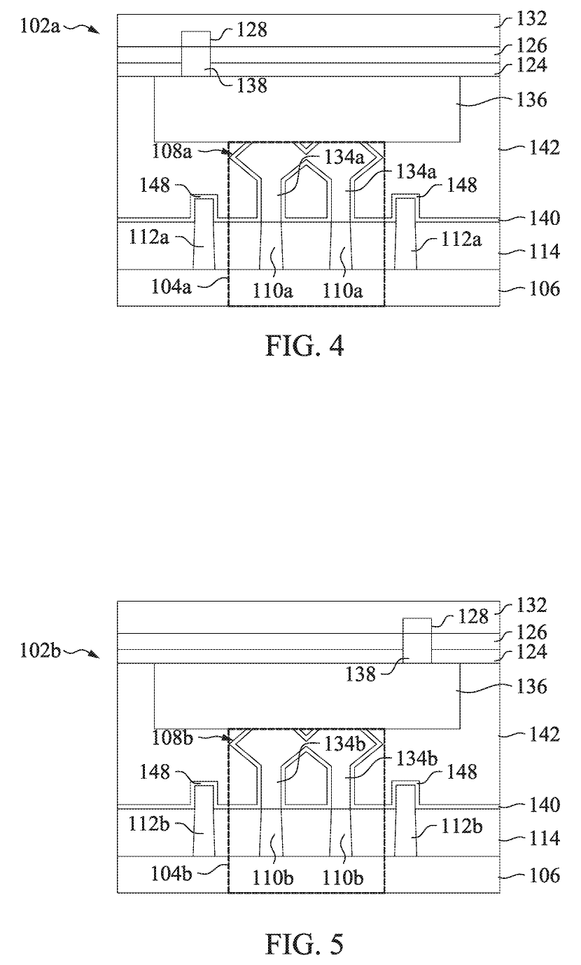

FIG. 4 is a schematic cross-sectional view, of an example FinFET device of FIG. 1, taken along section line C-C’, according to embodiments of the present disclosure. FIG. 5 is a schematic cross-sectional view, of another example FinFET device of FIG. 1, taken along section line D-D’, according to embodiments of the present disclosure.

As shown in FIG. 4, outside the gate region, the first FinFET device 102a may include the first S/D region 108a. For example, the first S/D region 108a may include n-type epitaxial S/D features 134a (e.g., in contact with the fin structures 110a of the first set). As shown in FIG. 5, outside the gate region, the second FinFET device 102b may include the second S/D region 108b. For example, the second S/D region 108b may include p-type epitaxial S/D features 134b (e.g., in contact with the fin structures 110b of the third set). In some embodiments, the epitaxial S/D features 134a, 134b (collectively 134) described herein may be made of SiC, SiP, SiGe, other suitable materials such as metal components, and/or combinations thereof. A S/D contact 136 may be formed over the S/D region 108a, 108b (collectively 108) and/or over the epitaxial S/D features 134. For example, the S/D contact 136 may be coupled to (e.g., in contact with) the epitaxial S/D features 134. In some embodiments, the S/D contact may be made of W, Co, Al, Cu, Ag, Au, other suitable materials, and/or combinations thereof. A S/D contact via 138 may be formed in the ILD layer 126 and extend from a metal line 128 of the IMD layer 132 to the S/D contact 136.

Outside the gate region, a sidewall spacer capping layer 148 may be formed over the second set of fin structures 112a. The sidewall spacer capping layer 148 may help control epitaxial growth. For example, the sidewall spacer capping layer 148 may be formed of silicon oxide, silicon nitride, silicon carbide, silicon oxynitride, silicon carbonitride, silicon oxycarbide, silicon oxycarbonitride, porous oxide, and/or combinations thereof. Outside the gate region, the CESL 140 is formed over the S/D features 134a/b. In some embodiments, the CESL 140 may be formed over the extra fin structures (e.g., fin structures 112a, of the second set, and fin structures 112b, of the fourth set). In some embodiments, the CESL 140 may be formed of silicon oxide, silicon nitride, silicon carbide, silicon oxynitride, silicon carbonitride, silicon oxycarbide, silicon oxycarbonitride, porous oxide, and/or combinations thereof. The CESL 140 may be located between the insulating material 114, of the STI feature, and another ILD layer 142, which is deposited over the CESL 140.

The extra fin structures 112a, 112b of FIGS. 1-5 provide certain benefits associated with device performance. For example, the extra fins enable adjustment of the work function of the gate electrode by changing the spatial composition of the WFM, in contrast to traditional techniques that are limited to material and thickness of the WFM. Furthermore, the spacing, height, count, and shape of the extra fins affects filling of the WFM, which further enables tuning of threshold voltage and/or leakage current. The extra fins can provide design density, reduce contact resistance, reduce loading effect during fin formation, enable tuning volume of electrode (e.g., based on fin height in the gate region), help contact positioning, reduce contact resistance, assist tuning shape and/or volume of epitaxial S/D (e.g., based on fin height outside the gate region).

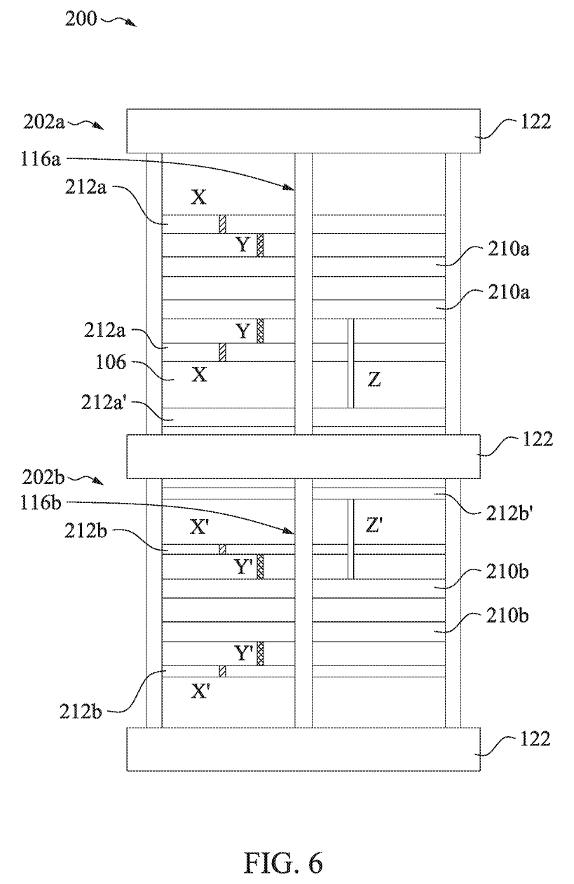

FIG. 6 is a schematic top view of an example semiconductor device 200 illustrating control of spacing of extra fin structures, according to embodiments of the present disclosure. Semiconductor device 200 is similar to semiconductor device 100 except for variations, with respect to the extra fins, in height, location, shape, count, and/or distance, etc. Certain aspects of the semiconductor device (e.g., S/D regions, metal lines, contact vias, and S/D contacts) are omitted from FIG. 6 for clarity. In some embodiments, the spacing may depend, at least in part, on fin width, fin shape, and/or fin volume. Therefore, two different examples are illustrated in FIG. 6. In the first FinFET device 202a, a width X of the extra fin structure 212a may be within a range of about 8 nm or less, such as about 6 nm to about 8 nm. A minimum spacing Y between the extra fin structure 212a and the adjacent fin structure 210a may be within a range of about 2X to about 3X (e.g., about 20 nm to about 22 nm). A maximum spacing Z between the extra fin structure 212a’ and the adjacent fin structure 210a may be within a range of about 5X to about 7X (e.g., about 32 nm to about 42 nm).

In the second FinFET device 202b, a width X’ of the extra fin structure 212b (e.g., measured at the top surface of the fin structure 212b) may be within a range of about 0.5X to about 1X (e.g., about 3 nm to about 8 nm, such as about 3 nm to about 6 nm or about 4 nm to about 8 nm). A minimum spacing Y’ between the extra fin structure 212b and the adjacent fin structure 210b may be within a range of about 4X’ to about 6X’ (e.g., about 20 nm to about 22 nm). A maximum spacing Z’ between the extra fin structure 212b’ and the adjacent fin structure 210b may be within a range of about 10X’ to about 14X’ (e.g., about 32 nm to about 42 nm).

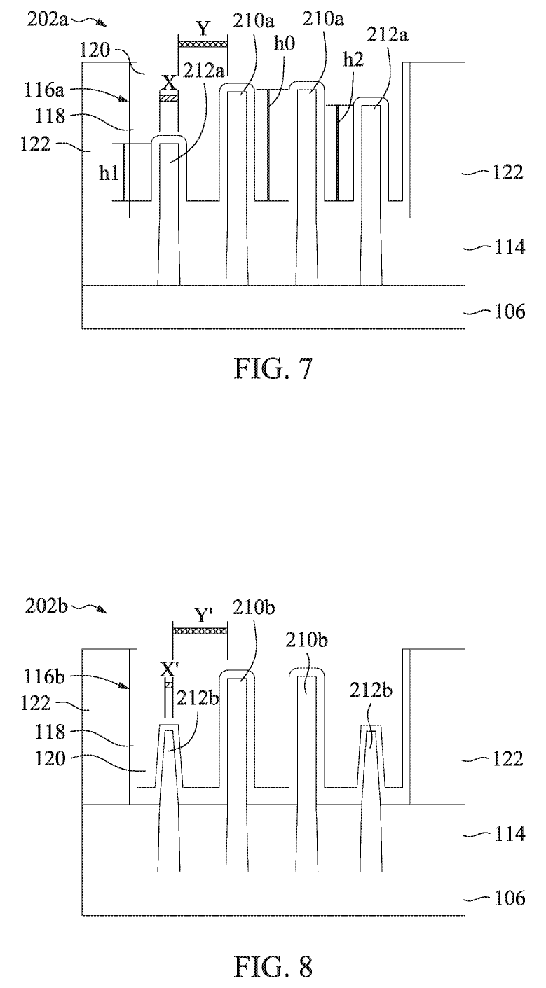

FIG. 7 is a schematic cross-sectional view, of an example FinFET device of FIG. 6, according to embodiments of the present disclosure. Certain aspects of the FinFET device (e.g., dielectric layers, conductive layer, contact vias, and IMD layer) are omitted from FIG. 7 for clarity. As shown in FIG. 7, the extra fin structure 212a of the first FinFET device 202a may be non-tapered (e.g., rectangular cross-section). For example, the width X of the fin structure 212a may be constant. The non-tapered shape corresponds to a volume of the fin structure 212a being greater than the volume of an analogous tapered fin structure, as described in more detail below.

As shown in FIG. 7, there may be differences in height between the active fin structures 210a and one or more extra fin structures 212a. For example, a height h0 of one or more active fin structures 210a may be greater than respective heights h1, h2 of the extra fin structures 212a. In some embodiments, a ratio of h1/h0 or h2/h0 may be within a range of 0 to 1, such as about 0.2 to about 0.9, about 0.4 to about 0.6, or about 0.5. As shown in FIG. 7, there may be differences in height between one or more of the extra fin structures 212a. For example, a first height h1 of a first extra fin structure 212a (e.g., on the left side of fin structures 210a) may be less than a second height h2 of a second extra fin structure 212a (e.g., on the right side of fin structures 210a). In some embodiments, a ratio of h1/h2 be within a range of 0 to 1, such as about 0.2 to about 0.95, about 0.4 to about 0.6, or about 0.5. In some other embodiments, the respective heights of the extra fin structures 212a may be equal.

FIG. 8 is a schematic cross-sectional view, of another example FinFET device of FIG. 6, according to embodiments of the present disclosure. Certain aspects of the FinFET device (e.g., dielectric layers, conductive layer, contact vias, and IMD layer) are omitted from FIG. 8 for clarity. As shown in FIG. 8, the extra fin structure 212b of the second FinFET device 202b may be tapered (e.g., decreasing in size towards the top surface). For example, the width X’ of the fin structure 212b may be narrowest at the top surface. For example, a tapered width (ratio of X’ to X) may be within a range of about 0.5x to about 1x. The tapered shape corresponds to a volume of the fin structure 212b being less than the volume of an analogous non-tapered fin structure (e.g., with a rectangular cross-section). As shown in FIG. 8, the heights of the extra fin structures 212b are equal. In some other embodiments, the respective heights of the extra fin structures 212b may be different.

The differences in fin spacing, fin width, fin shape, fin height, and fin volume, described above, can provide, independently or in combination, many different knobs for tuning device performance. Examples illustrating control of device performance, based on the various control knobs identified herein, are provided below.

FIGS. 9-12 are schematic cross-sectional views of example FinFET devices of FIGS. 1 or 6, according to embodiments of the present disclosure. FinFET devices 302, 402a, 402b, 502, 602 are similar to FinFET devices 102a, 102b, 202a, 202b except for variations in gate electrode material composition and, with respect to the extra fins, in height, location, shape, count, and/or distance, etc. Certain aspects of the FinFET devices (e.g., dielectric layers, conductive layer, contact vias, and IMD layer) are omitted from FIGS. 9-12 for clarity. In some embodiments, the FinFET devices may be patterned to deposit different compositions of WFM in the gate electrode 120, as described in more detail below. As used herein, the terms “pattern,” “patterned,” and “patterning” may refer to a multi-step process that includes, for example, forming a mask over an upper surface of a respective layer, patterning the mask using photolithography to remove portions of the mask and expose portions of the upper surface of the respective layer, etching through the patterned mask to remove portions of the respective layer, and/or removing the patterned mask using a suitable process (e.g., ashing or dissolution with a solvent, among other examples).

As shown in FIG. 9, a FinFET device 302 includes a first set of fin structures 310, a second set of extra fin structures 312/312’, and a gate 316 over both the first and second sets of fin structures. The gate 316 may include a gate electrode 320 with a plurality of (e.g., three) distinct material compositions. For example, the gate electrode 320 may include a first portion 320a (e.g., surrounding the first set of fin structures 310), a second portion 320b (e.g., surrounding a first extra fin structure 312), and a third portion 320c (e.g., surrounding a second extra fin structure 312’). In some embodiments, one or more of the first portion 320a, the second portion 320b, or the third portion 320c may have a material composition that is different from one or more other portions of the gate electrode 320. For example, all the material compositions may be different from each other. In some embodiments, material compositions of the second portion 320b and the third portion 320c may be the same as each other and may be different from the material composition of the first portion 320a. In some embodiments, the material compositions may include p-type dopants, n-type dopants, low resistance, high resistance, different work functions, etc. In some embodiments, material compositions and physical aspects of the extra fin structures 312/312’ may be implemented, independently or combined, to tune device performance. For example, as shown in FIG. 9, the height of the extra fin structure 312 located in the second portion 320b of the gate electrode 320 is less than the height of the extra fin structure 312’ located in the third portion 320c. This difference in height, independently or in combination with differences in material compositions between the second portion 320b and the third portion 320c, can provide improved (e.g., synergistic effects on) tuning of device performance. In some other embodiments, the respective heights of the extra fin structures 312/312’ may be equal.

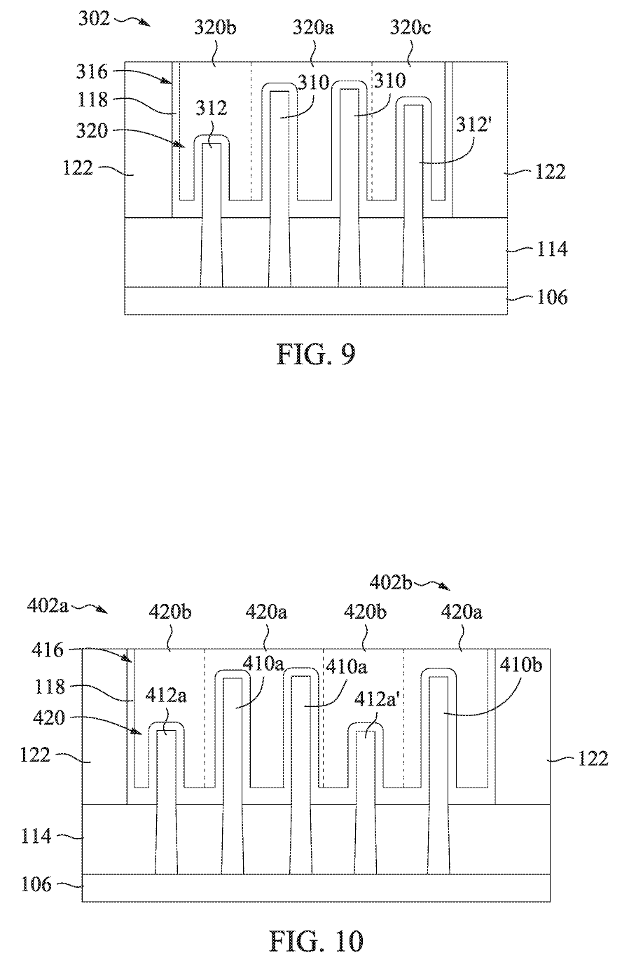

As shown in FIG. 10, another device 402a/b includes a first set of fin structures 410a of a first FinFET device 402a, a second set of fin structures 410b of a second FinFET device 402b, a third set of extra fin structures 412a/a’, and a gate 416 over all of the first, second, and third sets of fin structures. The gate 416 may include a gate electrode 420 with a plurality of (e.g., two) distinct material compositions. For example, the gate electrode 420 may include a first portion 420a (e.g., surrounding the first set of fin structures 410a and the second set of fin structures 410b) and a second portion 420b (e.g., surrounding a first extra fin structure 412a and a second extra fin structure 412a’). In some embodiments, the first portion 420a and the second portion 420b may be alternating. In some embodiments, the first portion 420a and the second portion 420b may have material compositions that are different from each other. In some other embodiments, the material compositions may be the same as each other. In some embodiments, the material compositions may include p-type dopants, n-type dopants, low resistance, high resistance, different work functions, etc.

As shown in FIG. 10, the second extra fin structure 412a’ is adjacent to (e.g., between) fin structures of both the first FinFET device 402a and the second FinFET device 402b. Therefore, the second extra fin structure 412a’ may be referred to as an “inner” fin, whereas the first extra fin structure 412a may be referred to as an “outer” fin. The proximity of the inner fin to the active fin structures on more than one side (e.g., both opposite sides) can provide improved tuning of device performance. As shown in FIG. 10, the heights of the extra fin structures 412a/a’ are equal. In some other embodiments, the respective heights of the extra fin structures 412a/a’ may be different.

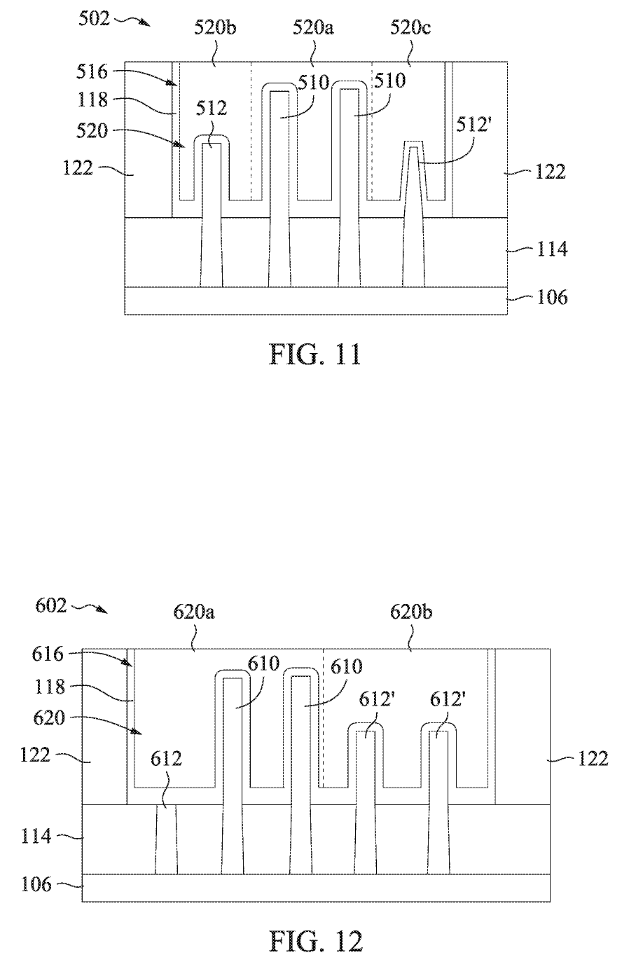

As shown in FIG. 11, a FinFET device 502 includes a first set of fin structures 510, a second set of extra fin structures 512/512’, and a gate 516 over both the first and second sets of fin structures. The gate 516 may include a gate electrode 520 with a plurality of (e.g., three) distinct material compositions. For example, the gate electrode 520 may include a first portion 520a (e.g., surrounding the first set of fin structures 510), a second portion 520b (e.g., surrounding a first extra fin structure 512), and a third portion 520c (e.g., surrounding a second extra fin structure 512’). In some embodiments, one or more of the first portion 520a, the second portion 520b, or the third portion 520c may have a material composition that is different from one or more other portions of the gate electrode 520. For example, all the material compositions may be different from each other. In some embodiments, material compositions of the second portion 520b and the third portion 520c may be the same as each other and may be different from the material composition of the first portion 520a. In some embodiments, the material compositions may include p-type dopants, n-type dopants, low resistance, high resistance, different work functions, etc.

In some embodiments, material compositions and physical aspects of the extra fin structures 512/512’ may be implemented, independently or combined, to tune device performance. For example, as shown in FIG. 11, the extra fin structure 512 located in the second portion 520b of the gate electrode 520 is non-tapered, and the extra fin structure 512’ located in the third portion 520c is tapered. The tapered shape corresponds to a volume of the extra fin structure 512’ being less than the volume of an analogous non-tapered fin structure 512. As shown in FIG. 11, the heights of the extra fin structures 512/512’ are equal. In some other embodiments, the respective heights of the extra fin structures 512/512’ may be different. The difference in shape/volume, independently or in combination with differences in material compositions between the second portion 520b and the third portion 520c, can provide improved (e.g., synergistic effects on) tuning of device performance.

As shown in FIG. 12, a FinFET device 602 includes a first set of fin structures 610, a second set of extra fin structures 612/612’, and a gate 616 over both the first and second sets of fin structures. The gate 616 may include a gate electrode 620 with a plurality of (e.g., two) distinct material compositions. For example, the gate electrode 620 may include a first portion 620a (e.g., surrounding the first set of fin structures 610 and a first extra fin structure 612) and a second portion 620b (e.g., surrounding second and third extra fin structures 612’). In some embodiments, the first portion 620a and the second portion 620b may have material compositions that are different from each other. In some other embodiments, the material compositions may be the same as each other. In some embodiments, the material compositions may include p-type dopants, n-type dopants, low resistance, high resistance, different work functions, etc.

In some embodiments, material compositions and physical aspects of the extra fin structures 612/612’ may be implemented, independently or combined, to tune device performance. For example, as shown in FIG. 12, the extra fin structure 612 does not extend into the gate 616 (e.g., ending below the gate dielectric 118). In some embodiments, the extra fin structure 612 may be formed, or cut, to have a height such that the top surface is below the gate 616. Device performance may be tuned based on the FinFET device 602 including the gate 616 without the extra fin structure 612.

As shown in FIG. 12, more than one (e.g., two) extra fin structures 612’ are located on the same side (e.g., on a first side, of first and second opposite sides) of the first set of fin structures 610. As shown in FIG. 12, the heights of the extra fin structures 612’ are equal. In some other embodiments, the respective heights of the extra fin structures 612’ may be different. The difference in count and/or distance, independently or in combination with differences in material compositions between the first portion 620a and the second portion 620b can provide improved (e.g., synergistic effects on) tuning of device performance.

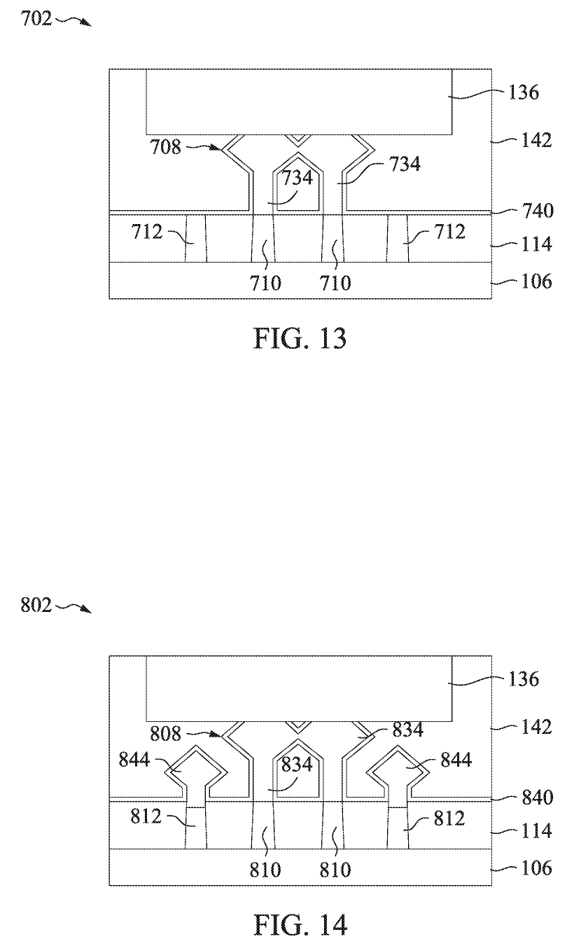

FIGS. 13-15 are schematic cross-sectional views, taken outside the gate region, of example FinFET devices of FIGS. 1 or 6, according to embodiments of the present disclosure. FinFET devices 702, 802, 902 are similar to FinFET devices 102a, 102b except for variations, with respect to the extra fins, in height, presence of a sidewall spacer capping layer, and/or presence of epitaxial S/D features, etc. Certain aspects of the FinFET devices (e.g., dielectric layers, conductive layer, contact vias, and IMD layer) are omitted from FIGS. 13-15 for clarity.

As shown in FIG. 13, a FinFET device 702 includes, outside the gate region, a S/D region 708, a first set of fin structures 710, and a second set of extra fin structures 712. The S/D region 708 may include epitaxial S/D features 734 (e.g., p-type or n-type). The epitaxial S/D features 734 may be formed over (e.g., in contact with) respective fin structures 710 of the first set. The FinFET device 702 may include a CESL 740 over the extra fin structures 712 and surrounding the S/D features 734.

As shown in FIG. 13, the extra fin structures 712 do not extend above the fin structures 710 (e.g., ending below the ILD layer 142). In some embodiments, the extra fin structures 712 may be formed, or cut, to have a height equal to or less than the height of the fin structures 710, such that top surfaces of the extra fin structures 712 are at or below top surfaces of the fin structures 710. In some embodiments, the CESL 740 may be flat (e.g., lying in a plane that extends over the top surfaces of the extra fin structures 712). Device performance may be tuned based on the FinFET device 702 including the extra fin structures 712 that are cut.

As shown in FIG. 14, a FinFET device 802 includes, outside the gate region, a S/D region 808, a first set of fin structures 810, and a second set of extra fin structures 812. The S/D region 808 may include epitaxial S/D features 834 (e.g., p-type or n-type). The epitaxial S/D features 834 may be formed over (e.g., in contact with) respective fin structures 810 of the first set. The FinFET device 802 may include a CESL 840 surrounding the S/D features 834. The FinFET device 802 may include epitaxial features 844. The epitaxial features 844 may be formed over (e.g., in contact with) respective extra fin structures 812 of the second set. The epitaxial features 844 may be separated from, or non-merging with, the epitaxial S/D features 834 (e.g., with the ILD layer 142 in between). In some embodiments, greater spacing between the extra fin structures 812 and adjacent fin structures 810 may further prevent merging. In some embodiments, the epitaxial features 844 may be formed using the same process as (e.g., concurrently with) the epitaxial S/D features 834. The CESL 840 may surround the epitaxial features 844.

As shown in FIG. 14, the extra fin structures 812 do not extend above the fin structures 810 (e.g., ending below the ILD layer 142). In some embodiments, the extra fin structures 812 may be formed, or cut, to have a height equal to or less than the height of the fin structures 810, such that top surfaces of the extra fin structures 812 are at or below top surfaces of the fin structures 810. In some embodiments, the extra fin structures 812 may be lower than the fin structures 810 and the epitaxial features 844 may extend to a depth that is below the top surface of the insulating material 114 of the STI feature. Device performance may be tuned based on the FinFET device 802 including the epitaxial features 844.

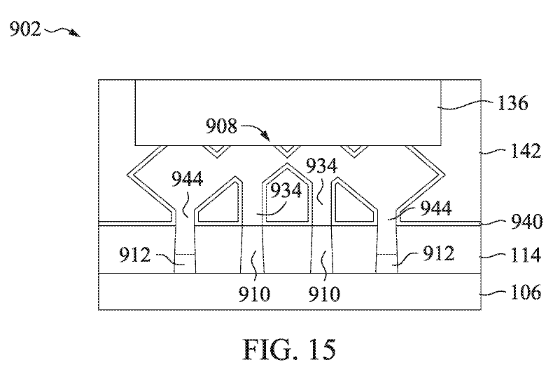

As shown in FIG. 15, a FinFET device 902 includes, outside the gate region, a S/D region 908, a first set of fin structures 910, and a second set of extra fin structures 912. The S/D region 908 may include epitaxial S/D features 934 (e.g., p-type or n-type). The epitaxial S/D features 934 may be formed over (e.g., in contact with) respective fin structures 910 of the first set. The FinFET device 902 may include a CESL 940 surrounding the S/D features 934. The FinFET device 902 may include epitaxial features 944. The epitaxial features 944 may be similar to the epitaxial features 844 shown in FIG. 14. The epitaxial features 944 may be formed over (e.g., in contact with) respective extra fin structures 912 of the second set. The epitaxial features 944 may be merged with the epitaxial S/D features 934. In some embodiments, the epitaxial features 944 may be formed using the same process as (e.g., concurrently with) the epitaxial S/D features 934. The CESL 940 may surround the epitaxial features 944.

As shown in FIG. 15, the extra fin structures 912 do not extend above the fin structures 910 (e.g., ending below the ILD layer 142). In some embodiments, the extra fin structures 912 may be formed, or cut, to have a height equal to or less than the height of the fin structures 910, such that top surfaces of the extra fin structures 912 are at or below top surfaces of the fin structures 910. In some embodiments, the extra fin structures 912 may be lower than the fin structures 910 and the epitaxial features 944 may extend to a depth that is below the top surface of the insulating material 114 of the STI feature. Device performance may be tuned based on the FinFET device 902 including the epitaxial features 944.

Comparing FIG. 14 and 15, the extra fin structures 912 are shorter than the extra fin structures 812. The shorter fin structures and/or greater depth may cause the epitaxial features 944 to grow larger (e.g., wider), which may promote merging and provide a larger landing area for the S/D contact 136. As a result of the larger size of the epitaxial features 944 and/or the larger landing area for the S/D contact 136, at least compared to the epitaxial features 844 of FIG. 14, for example, device resistance may be lowered (with corresponding higher current), which may be particularly beneficial for device performance.

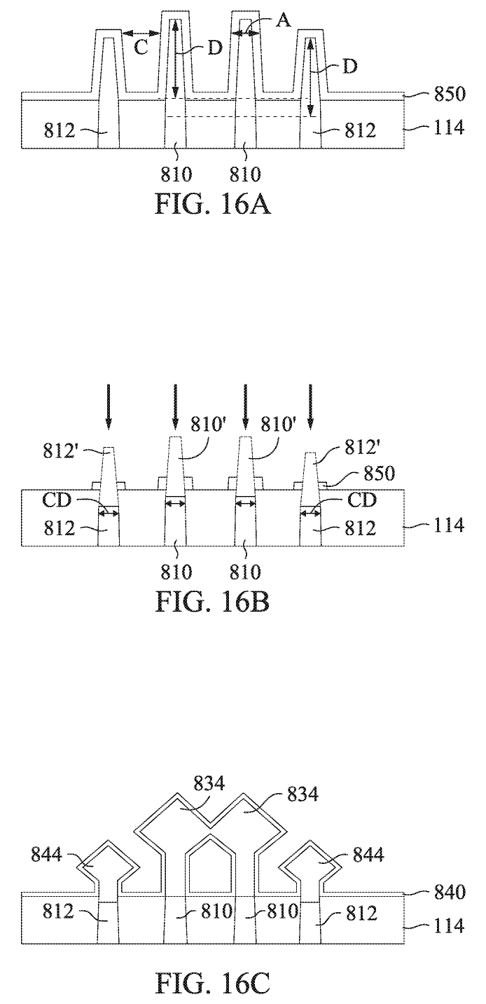

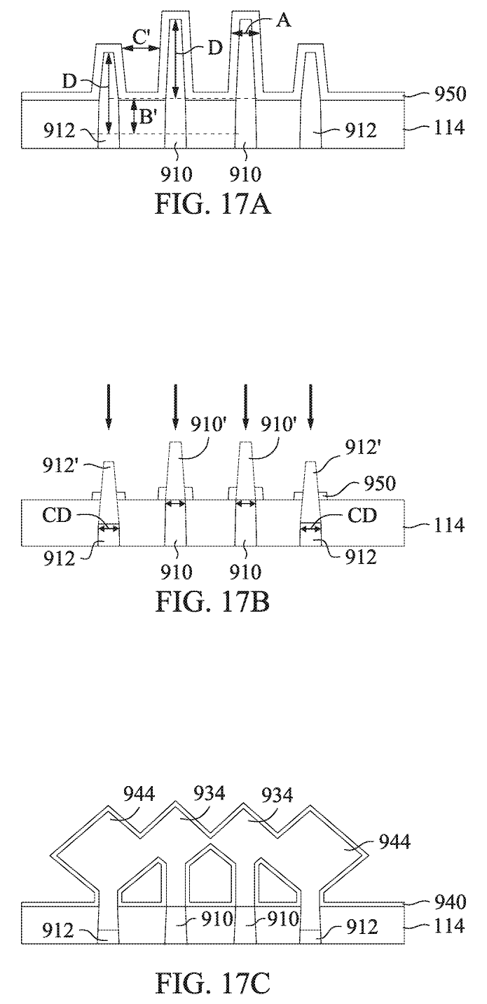

FIGS. 16A-16C schematically illustrate various stages of forming the epitaxial features 834/844 of FIG. 14, according to embodiments of the present disclosure. As shown in FIG. 16A, the fin structures 810/812 are formed and a spacer material 850 is deposited over the fin structures 810/812. Certain dimensions of the fin structures 810/812 are indicated, including fin width A, fin-to-fin spacing C, and fin height D. These dimensions are described in more detail below with respect to FIG. 17A. As shown in FIG. 16B, an etch back process is performed to remove portions of the fin structures 810/812 and open corresponding recesses 810’/812’ for defining a growth pattern of the epitaxial features 834/844. As shown in FIG. 16C, the epitaxial features 834/844 are formed and a CESL 840 is deposited over the epitaxial features 834/844.

FIGS. 17A-17C schematically illustrate various stages of forming the epitaxial features 934/944 of FIG. 15, according to embodiments of the present disclosure. As shown in FIG. 17A, the fin structures 910/912 are formed and the spacer material 950 is deposited over the fin structures 910/912. In some embodiments, the fin-to-fin spacing C’ of the fin structures 910/912 may be less than the fin-to-fin spacing C of the fin structures 810/812. For example, the fin-to-fin spacing C’ may be in a range between 2*A and 0.85*C. In some embodiments, a depth B’ of the fin structures 910/912 may be greater than a corresponding depth of the fin structures 810/812. For example, the depth B’ may be greater than or equal to 0.4*D. As shown in FIG. 17B, an etch back process is performed to remove portions of the fin structures 910/912 and open corresponding recesses 910’/912’ for defining a growth pattern of the epitaxial features 934/944. As shown in FIG. 17C, the epitaxial features 934/944 are formed and a CESL 940 is deposited over the epitaxial features 934/944.

Comparing FIGS. 16A-16C and 17A-17C, the recesses 912’ are greater in depth than the recesses 812’, the top surfaces of the resultant fin structures 912, adjacent the recesses 912’, have wider critical dimension (CD) than the top surfaces of the resultant fin structures 812, adjacent the recesses 812’, and the epitaxial features 944 are larger than the epitaxial features 844, as described above with respect to FIG. 14 and 15.

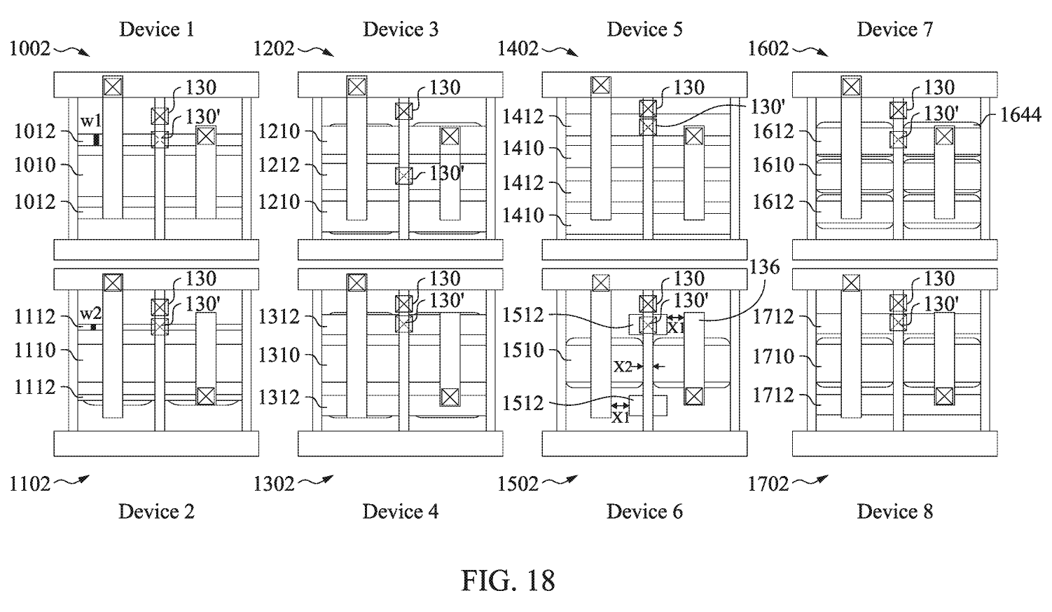

FIG. 18 illustrates schematic top views of example semiconductor devices that incorporate one or more aspects described herein, according to embodiments of the present disclosure. Certain aspects of the semiconductor devices (e.g., metal lines) are omitted from FIG. 18 for clarity.

Device 1 illustrates a FinFET device 1002 with extra fin structures 1012 of first width w1. With respect to Device 1, and the other devices illustrated in FIG. 18, the extra fin structures may be active and, as a result, may provide a transistor function. Device 1 may include one or more active fin structures 1010 (e.g., 2-3 active fin structures located within the active area defined by box 1010). In some embodiments, the extra fin structures 1012 may have different heights (e.g., high and low fin heights). For example, Device 1 may incorporate one or more aspects of the FinFET device 202a (FIG. 7) and/or the FinFET device 302 (FIG. 9). Device 2 illustrates a FinFET device 1102 with extra fin structures 1112 that are small (e.g., narrower or tapered), such as having a second width w2 that is less than the first width w1 of Device 1. Device 2 may include one or more active fin structures 1110 (e.g., 2-3 active fin structures located within the active area defined by box 1110). In some embodiments, Device 2 may incorporate one or more aspects of the FinFET device 202b (FIG. 8) and/or the FinFET device 502 (FIG. 11). Device 3 illustrates a FinFET device 1202 with one or more extra fin structures 1212 that are inner fin structures (e.g., 1-2 inner fin structures located within the active area defined by box 1212). For example, the one or more inner fin structures may be between the active fin structures 1210. In some embodiments, Device 3 may incorporate one or more aspects of the FinFET device 402a/b (FIG. 10). Device 4 illustrates a FinFET device 1302 with one or more extra fin structures 1312 that are outer fin structures (e.g., two sets of outer fin structures are shown). The one or more outer fin structures may be outside (e.g., surrounding) the active fin structures 1310. Each set of outer fin structures may include one or more outer fin structures (e.g., 1-2 outer fin structures located within the active areas defined by respective boxes 1312). In some embodiments, Device 4 may incorporate one or more aspects of the FinFET device 602 (FIG. 12). Device 5 illustrates a FinFET device 1402 with one or more extra fin structures 1412 that are alternating with the active fin structures 1410. For example, the extra fin structures 1412 may include inner fin structures and outer fin structures (e.g., one set of inner fin structures and another set of outer fin structures are shown). Each set of inner and outer fin structures may include one or more fin structures (e.g., 1-2 fin structures located within the active areas defined by respective boxes 1412).

Device 6 illustrates a FinFET device 1502 with extra fin structures 1512 that are short lengthwise (e.g., extending only through the gate region (e.g., channel) and/or not continuing through the S/D region). For example, the short fin structures may be spaced from the S/D contacts 136 by a distance X1. When gate length is X2, a ratio of X1/X2 is within a range of 0.03 to 1.5. Device 6 may include one or more short fin structures (e.g., two or more short fin structures, such as two short fin structures). In some embodiments, the portions of the short fin structures outside the gate region may be cut. Device 6 may include one or more active fin structures 1510 (e.g., 2-3 active fin structures located within the active area defined by box 1510). In some embodiments, the epitaxial structures of Device 6 may be non-merging. In some embodiments, Device 6 may incorporate one or more aspects of the FinFET device 702 (FIG. 13).

Device 7 illustrates a FinFET device 1602 with extra fin structures 1612 that include small epitaxial features 1644 outside the gate region (e.g., dummy features). Device 7 may include one or more small epitaxial features 1644 (e.g., only one small epitaxial feature is shown per extra fin structure). Device 7 may include one or more active fin structures 1610 (e.g., 1-2 active fin structures located within the active area defined by box 1610). In some embodiments, the small epitaxial structures 1644 of Device 7 may be non-merging. In some embodiments, Device 7 may incorporate one or more aspects of the FinFET device 802 (FIG. 14).

Device 8 illustrates a FinFET device 1702 with extra fin structures 1712 that are capped outside the gate region (e.g., with a spacer material). Device 8 may include one or capped fin structures. Device 8 may include one or more active fin structures 1710 (e.g., 2-3 active fin structures located within the active area defined by box 1710). In some embodiments, the epitaxial structures of Device 8 may be non-merging. In some embodiments, Device 8 may incorporate one or more aspects of the FinFET device 102a/b (FIG. 4 or 5).

The example semiconductor devices of FIG. 18 illustrate two different optional positions of the gate contact via. For example, the gate contact via may be configurable between a first position 130 that is not overlapping the extra fin structure to a second position 130’ (shown in phantom) that is overlapping the extra fin structure. The position of the gate contact via may be provide additional adjustment for the work function and/or tuning for Vₜ.

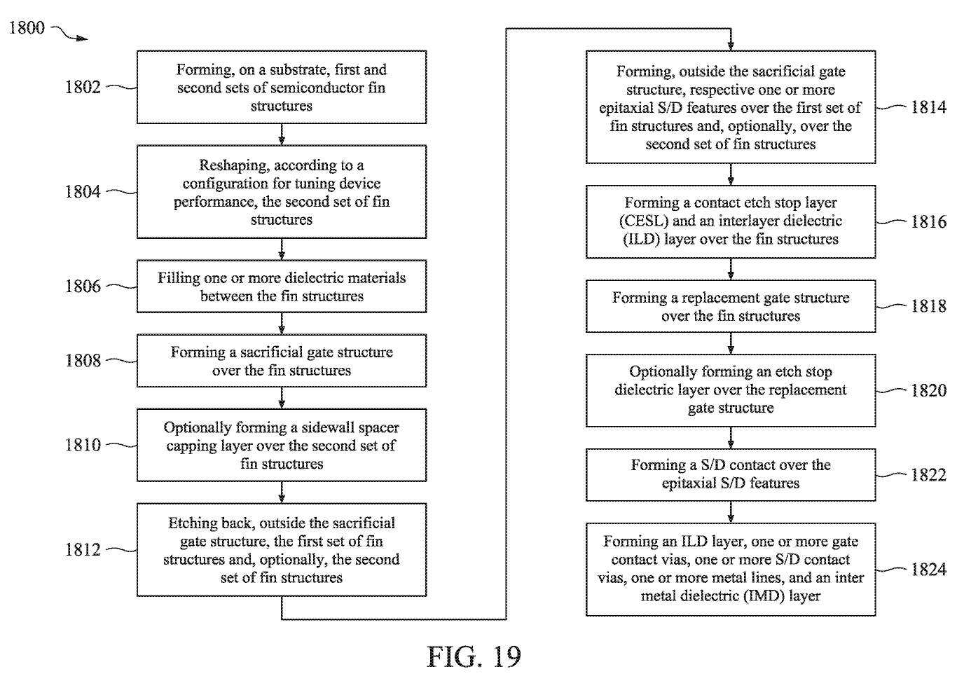

FIG. 19 is a flow chart of a method 1800 of forming a FinFET of a semiconductor device, according to embodiments of the present disclosure. The method 1800 may be understood to relate to any embodiments, or combinations of embodiments, described herein and/or illustrated in FIGS. 1-18, without limitation. At block 1802, the method 1800 may include forming, on a substrate, first and second sets of semiconductor fin structures. For example, the semiconductor fin structures may include a first set of fin structures that are active and a second set of fin structure that are extra. The second set of fin structures may be either active or non-active as described above. At block 1804, the method 1800 may include reshaping, according to a configuration for tuning device performance, the second set of fin structures. For example, the second set of fin structures may be reshaped relative to the first set of fin structures. In some embodiments, the method 1800 may include selectively reshaping the second set of fin structures to improve device performance. For example, selectively reshaping (e.g., using a patterning process) the second set of fin structures may include one or more of: causing the second set of fin structures to be different height from the first set of fin structures, causing first and second fin structures, of the second set, to be different heights from each other; causing one or more fin structures, of the second set, to be tapered; causing at least one inner fin structure, of the second set, to be located between a first active fin structure, of the first set, and a second active fin structure of another set of active fin structures; or causing at least two fin structures, of the second set, to be located on a first side, of first and second opposite sides, of the first set of fin structures.

At block 1806, the method 1800 may include filling one or more dielectric materials between the fin structures. For example, the one or more dielectric materials may include a shallow trench isolation (STI) feature and one or more other dielectric layers. For example, the one or more dielectric materials may be deposited over and/or around the first set of fin structures and the second set of fin structures. At block 1808, the method 1800 may include forming a sacrificial (“dummy”) gate structure over the fin structures. For example, the sacrificial gate may include a sacrificial gate dielectric layer and a sacrificial gate electrode layer that are deposited and subsequently patterned to form the sacrificial gate structure.

At block 1810, the method 1800 may include optionally forming a sidewall spacer capping layer over the second set of fin structures. In some embodiments, the sidewall spacer capping layer is formed before block 1812 to prevent etching back of the second set of fin structures. In some embodiments, the sidewall spacer capping layer is formed before block 1814 to prevent epitaxial growth on the second set of fin structures. At block 1812, the method 1800 may include etching back, outside the sacrificial gate structure, the first set of fin structures and, optionally, the second set of fin structures. At block 1814, the method 1800 may include forming, outside the sacrificial gate structure, respective one or more epitaxial S/D features over the first set of fin structures and, optionally, over the second set of fin structures.

In some embodiments, the method 1800 may include selectively controlling the second set of fin structures to improve device performance. For example, as described in more detail above, selectively controlling the second set of fin structures, outside a gate region of the FinFET, may include one or more of: forming a spacer material over the second set of fin structures; causing the second set of fin structures to be equal to or less than a height of the first set of fin structures; causing the second set of fin structures to include epitaxial features that are non-merging with epitaxial S/D features of the first set of fin structures; or causing the second set of fin structures to include epitaxial features that are merging with the epitaxial S/D features of the first set of fin structures.

At block 1816, the method 1800 may include forming a CESL and an ILD layer (“ILD0") over the fin structures. At block 1818, the method 1800 may include forming a replacement gate structure over the fin structures. For example, forming the replacement gate structure may include depositing a gate dielectric over the fin structures and depositing, subsequently, a gate electrode over the gate dielectric. In some embodiments, the gate electrode may be deposited using a single deposition process. In some other embodiments, for example illustrated in FIGS. 9-12, the gate electrode may be deposited using a plurality of sequential deposition processes to form different portions of the gate electrode with a plurality of distinct material compositions. For example, separate patterning and deposition processes may be applied to form different portions of the gate electrode.

At block 1820, the method 1800 may include optionally forming an etch stop dielectric layer over the replacement gate structure. At block 1822, the method 1800 may include forming a S/D contact over the epitaxial S/D features. At block 1824, the method 1800 may include forming an ILD layer, one or more gate contact vias, one or more S/D contact vias, one or more metal lines, and an inter metal dielectric (IMD) layer.

It will be understood that not all advantages have been necessarily discussed herein, no particular advantage is required for all embodiments or examples, and other embodiments or examples may offer different advantages.

Some embodiments of the present provide a semiconductor device, comprising: a Fin Field Effect Transistor (FinFET), including: a first set of fin structures that are active; a source/drain (S/D) region in contact with the first set of fin structures; a second set of fin structures separated, via a shallow trench isolation (STI) feature, from the first set of fin structures; a contact etch stop layer (CESL) over the S/D region and over the second set of fin structures, wherein the second set of fin structures includes one or more non-active fin structures that are in contact with the CESL without being in contact with the S/D region; and a gate over the first set of fin structures and over the second set of fin structures, the gate including: a gate dielectric; and a gate electrode over the gate dielectric.

Some embodiments of the present disclosure provide method of manufacturing a semiconductor device, comprising: forming, on a substrate, first and second sets of fin structures; reshaping the second set of fin structures without affecting the first set of fin structures; filling one or more dielectric materials between fin structures of the first and second sets of fin structures; forming a sacrificial gate structure over the first and second sets of fin structures; etching back, outside the sacrificial gate structure, the first set of fin structures; forming, outside the sacrificial gate structure, respective one or more epitaxial S/D features over the first set of fin structures; forming a CESL and an interlayer dielectric (ILD) layer over the fin structures; and forming a replacement gate over the first and second sets of fin structures.

Some embodiments of the present disclosure provide a method of manufacturing a semiconductor device, comprising: forming a FinFET, including: a first set of fin structures that are active; a S/D region in contact with the first set of fin structures; a second set of fin structures separated, via an STI feature, from the first set of fin structures; a contact etch stop layer (CESL) over the S/D region and over the second set of fin structures, wherein the second set of fin structures includes one or more non-active fin structures that are in contact with the CESL without being in contact with the S/D region; and a gate over the first set of fin structures and over the second set of fin structures, the gate including: a gate dielectric; and a gate electrode over the gate dielectric.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a substrate; and
a Fin Field-Effect Transistor (FinFET) disposed over the substrate, the FinFET comprising:
a first set of fin structures that are active, the first set of fin structures comprising a semiconductor material;
a source/drain (S/D) region in contact with the first set of fin structures;
a second set of fin structures comprising the semiconductor material, the second set of fin structures being separated from the first set of fin structures by a shallow trench isolation (STI) feature, wherein the second set of fin structures are separated from the S/D region by a dielectric material; and
a gate extending over the first set of fin structures and over the second set of fin structures, the gate including a gate dielectric and a gate electrode over the gate dielectric,
wherein a height of at least one fin structure of the second set is less than a height of each fin structure of the first set.

2. The semiconductor device of claim 1, wherein the second set of fin structures includes a first non-active fin structure and a second non-active fin structure, and wherein a height of the first non-active fin structure differs from a height of the second non-active fin structure.

3. The semiconductor device of claim 1, wherein the second set of fin structures includes a first non-active fin structure disposed on a first side of the first set of fin structures and a second non-active fin structure disposed on a second side of the first set of fin structures opposite the first side, and wherein a minimum spacing between the first non-active fin structure and an immediately adjacent fin structure of the first set is in a range of about two times to about three times a width of the first non-active fin structure.

4. The semiconductor device of claim 3, wherein a maximum spacing between the second non-active fin structure and an immediately adjacent fin structure of the first set is in a range of about five times to about seven times the width of the first non-active fin structure.

5. The semiconductor device of claim 1, further comprising a second FinFET disposed over the substrate and including a third set of fin structures that are active and comprise the semiconductor material, wherein the second set of fin structures includes an inner non-active fin structure laterally disposed between the first set of fin structures and the third set of fin structures.

6. The semiconductor device of claim 1, further comprising a contact etch stop layer (CESL) disposed over the S/D region and over the second set of fin structures, wherein the CESL is in contact with at least one fin structure of the second set without that fin structure being in contact with the S/D region.

7. The semiconductor device of claim 1, wherein the semiconductor material comprises one or more of silicon (Si), germanium (Ge), silicon germanium (SiGe), silicon carbide (SiC), gallium arsenide (GaAs), or gallium nitride (GaN).

8. A semiconductor device, comprising:
a substrate; and
a Fin Field-Effect Transistor (FinFET) disposed over the substrate, the FinFET comprising:
a first set of semiconductor fin structures that are active;
a second set of semiconductor fin structures that are non-active, the second set of semiconductor fin structures being separated from the first set of semiconductor fin structures by an insulating material; and
a gate disposed over the first and second sets of semiconductor fin structures, the gate including a gate dielectric and a gate electrode over the gate dielectric,
wherein at least one non-active fin structure of the second set has a cross-sectional shape that differs from a cross-sectional shape of each active fin structure of the first set.

9. The semiconductor device of claim 8, wherein the at least one non-active fin structure of the second set is tapered such that a width of the at least one non-active fin structure decreases toward a top surface of the at least one non-active fin structure, and wherein each active fin structure of the first set is non-tapered.

10. The semiconductor device of claim 9, wherein a ratio of a width of the at least one non-active fin structure at the top surface to a width of the at least one non-active fin structure at a bottom portion thereof is in a range of about 0.5 to about 1.

11. The semiconductor device of claim 8, wherein the second set of semiconductor fin structures includes a first non-active fin structure that is non-tapered and a second non-active fin structure that is tapered.

12. The semiconductor device of claim 8, wherein the second set of semiconductor fin structures includes a first non-active fin structure having a top surface located below the gate dielectric such that the first non-active fin structure does not extend into the gate.

13. The semiconductor device of claim 8, wherein the gate electrode comprises a first portion having a first material composition and a second portion having a second material composition different from the first material composition, wherein the first portion surrounds at least one active fin structure of the first set, and wherein the second portion surrounds the at least one non-active fin structure of the second set.

14. The semiconductor device of claim 8, wherein the second set of semiconductor fin structures includes at least two non-active fin structures disposed on a same side of the first set of semiconductor fin structures.

15. A method of forming a semiconductor device, comprising:
forming, on a substrate, a first set of semiconductor fin structures and a second set of semiconductor fin structures;
reshaping the second set of semiconductor fin structures, according to a configuration for tuning device performance, without affecting the first set of semiconductor fin structures, such that, after the reshaping, the second set of semiconductor fin structures is non-active;
filling an insulating material between fin structures of the first and second sets;
forming, outside a gate region and on the first set of semiconductor fin structures, one or more epitaxial source/drain (S/D) features, the one or more epitaxial S/D features being absent from the second set of semiconductor fin structures; and
forming a gate over the first and second sets of semiconductor fin structures, the gate including a gate dielectric and a gate electrode over the gate dielectric.

16. The method of claim 15, wherein reshaping the second set of semiconductor fin structures comprises etching the second set of semiconductor fin structures to a height less than a height of the first set of semiconductor fin structures.

17. The method of claim 15, wherein reshaping the second set of semiconductor fin structures comprises tapering at least one semiconductor fin structure of the second set such that the at least one semiconductor fin structure has a width that decreases toward a top surface of the at least one semiconductor fin structure.

18. The method of claim 15, wherein reshaping the second set of semiconductor fin structures comprises causing a first semiconductor fin structure of the second set to have a first height and causing a second semiconductor fin structure of the second set to have a second height different from the first height.

19. The method of claim 15, wherein reshaping the second set of semiconductor fin structures comprises etching at least one semiconductor fin structure of the second set such that, after forming the gate, a top surface of the at least one semiconductor fin structure is located below the gate dielectric.

20. The method of claim 15, further comprising, prior to forming the one or more epitaxial S/D features, forming a sidewall spacer capping layer over the second set of semiconductor fin structures to prevent epitaxial growth on the second set of semiconductor fin structures.
